(19) United States
(12) Patent Application Publication
(10) Pub. No.: US 2017/0023653 A1
(43) Pub. Date: Jan. 26, 2017

(54) OPTICALLY PUMPED MAGNETOMETER AND MAGNETIC SENSING METHOD

(71) Applicant: CANON KABUSHIKI KAISHA, Tokyo (JP)

(72) Inventors: Tetsuo Kobayashi, Kyoto-shi (JP); Yosuke Ito, Kyoto-shi (JP); Sunao Ichihara, Tokyo (JP); Natsuhiko Mizutani, Tokyo (JP)

(21) Appl. No.: 15/203,485

(22) Filed: Jul. 6, 2016

(30) Foreign Application Priority Data
Jul. 21, 2015 (JP) 2015-143660

(51) Int. Cl. G01R 33/26

(52) U.S. Cl. CPC G01R 33/26

(57) ABSTRACT

An optically pumped magnetometer and a magnetic sensing method are provided. The optically pumped magnetometer is an atomic magnetic sensor that measures a magnetic field at multiple locations in a single cell and that can separate and simultaneously measure magnetic information of spatially different places in a configuration in which a plurality of probe lights or pump lights are radiated. An optically pumped magnetometer and a magnetic sensing method are provided which, by radiating a relaxing light between a plurality of measurement regions constituted by a pump light and a probe light, prevent mixing of spin polarization and separate spatially different magnetic signals with high accuracy.

### BACKGROUND OF THE INVENTION

Field of the Invention

The present invention relates to a sensing method and a magnetometer that measure a magnetic field intensity, and more particularly to an optically pumped magnetometer and a magnetic sensing method that utilize electron spin or nuclear spin of atoms.

Description of the Related Art

Optically pumped magnetometers are described in Nature, Vol.422, pp.596-599, 2003, Japanese Patent Application Laid-Open No. 2012-202753 and Japanese Patent Application Laid-Open No. 2012-159402. The optically pumped magnetometer described in Nature, Vol.422, pp.596-599, 2003 includes a cell encapsulating alkali metal gas, a light source for a pump light and a light source for a probe light. The optically pumped magnetometer measures rotation of a plane of polarization of a probe light based on the spin of an atom group that is rotated by a target magnetic field to be measured and polarized by a pump light. Nature, Vol.422, pp.596-599, 2003 also illustrates a method of changing an intersection region of a probe light and a pump light in each measurement separately measure magnetic signals at different locations on the optical path of the pump light. Further, Japanese Patent Application Laid-Open No. 2012-202753 illustrates a configuration in which a plurality of intersection regions between a probe light and a pump light are provided within a single cell. Furthermore, Japanese Patent Application Laid-Open No. 2012-159402 illustrates a configuration in which induction light that stimulates photo-stimulated desorption of alkali metal atoms from a cell wall surface is used as a third light that is different from probe light and pump light.

In Nature, Vol.422, pp.596-599, 2003, An optically pumped magnetometer separates and measures a probe light in the pump light direction, by use of a linear sensor array, to simultaneously measure a magnetic field intensity at different positions on the optical path of a pump light. According to Japanese Patent Application Laid-Open No. 2012-202753, a plurality of probe lights and pump light are simultaneously radiated to create intersection regions at a plurality of locations, therefore the magnetic field intensity at different positions is measured simultaneously. However, in each of these configurations of the publications, spin polarizations of alkali metal used for measurement become mixed together due to diffusion of atoms or spin-exchange collisions, and consequently magnetic signals that are spatially different are measured in a mixed state.

### SUMMARY OF THE INVENTION

An object of the present invention is to provide an optically pumped atomic magnetometer which is an atomic magnetic sensor that measures multiple locations in a single cell and which can separate and simultaneously measure magnetic information of spatially different places in a configuration that radiates a plurality of probe lights or pump lights, and also provide a magnetic sensing method.

According to one aspect of the present invention, there is provided an optically pumped magnetometer including: a single cell encapsulating alkali metal atoms; one or a plurality of pump light optical systems that introduces a pump light having a circularly polarized light component into the cell; one or a plurality of probe light optical systems that introduces a probe light having a linearly polarized light component into the cell so as to intersect with the pump light introduced into the cell; a relaxing light optical system that introduces a plurality of relaxing lights having an action that relaxes spin polarization between a plurality of intersection regions constituted by the pump light and the probe light; a detection unit that detects a signal that reflects a rotation angle of a plane of polarization of the probe light after intersecting with the pump light; and an information acquisition unit that acquires information relating to a magnetic field intensity of each of the different locations, based on the signal that is detected by the detection unit; wherein the relaxing light optical system includes a unit that prevents mixing of spin polarizations between intersection regions.

Further features of the present invention will become apparent from the following description of exemplary embodiments with reference to the attached drawings.

### BRIEF DESCRIPTION OF THE DRAWINGS

FIGS. 1A, 1B and 1C illustrate examples of an optically pumped magnetometer. FIG. 1A illustrates an example of an optically pumped magnetometer that uses two pump lights, two probe lights and two detection units. FIG. 1B illustrates an example of an optically pumped magnetometer that uses two pump lights, one probe light and one detection unit. FIG. 1C illustrates an example of an optically pumped magnetometer that uses one pump light, one probe light and two detection units.

FIG. 2 is a perspective view illustrating the configuration of an optically pumped magnetometer according to a first embodiment of the present invention.

FIG. 3 is a perspective view illustrating the configuration of a measurement region of the optically pumped magnetometer according to the first embodiment of the present invention.

FIG. 4 is a schematic diagram illustrating an example of polarization measurement in the optically pumped magnetometer according to the first embodiment of the present invention.

FIG. 5 is a perspective view illustrating the configuration of an optically pumped magnetometer according to a second embodiment of the present invention.

FIG. 6 is a schematic diagram illustrating the configuration of an optically pumped magnetometer according to a third embodiment of the present invention.

FIG. 7 is a schematic diagram illustrating an example of a pump light modulation system in the optically pumped magnetometer according to the third embodiment of the present invention.

FIG. 8 is a schematic diagram illustrating a configuration in a case where a pump light modulation system and a relaxing light optical system are combined according to the third embodiment of the present invention.

FIG. 9 is a schematic diagram illustrating a configuration of an optically pumped magnetometer according to a fourth embodiment of the present invention.

FIG. 10 is a schematic diagram illustrating an example of a relaxing light shaping unit in the optically pumped magnetometer according to the fourth embodiment of the present invention.

### DESCRIPTION OF THE EMBODIMENTS

Preferred embodiments of the present invention will now be described in detail in accordance with the accompanying drawings.

An optically pumped magnetometer according to an exemplary embodiment of the present invention acquires information relating to a magnetic field intensity of a measurement region by causing a pump light having a circularly polarized light component and a probe light having a linearly polarized light component to intersect at the measurement region in a single cell encapsulating alkali metal atoms, and detecting the probe light that has passed through the measurement region. The optically pumped magnetometer also has a relaxing light optical system that relaxes the spin polarization of alkali metal atoms that are present between first and second measurement regions that are provided inside the cell. By relaxing spin polarization that is present between the first and second measurement regions, the influence that the spin polarization of alkali metal atoms of one of the measurement regions has on the spin polarization of the other measurement region can be reduced.

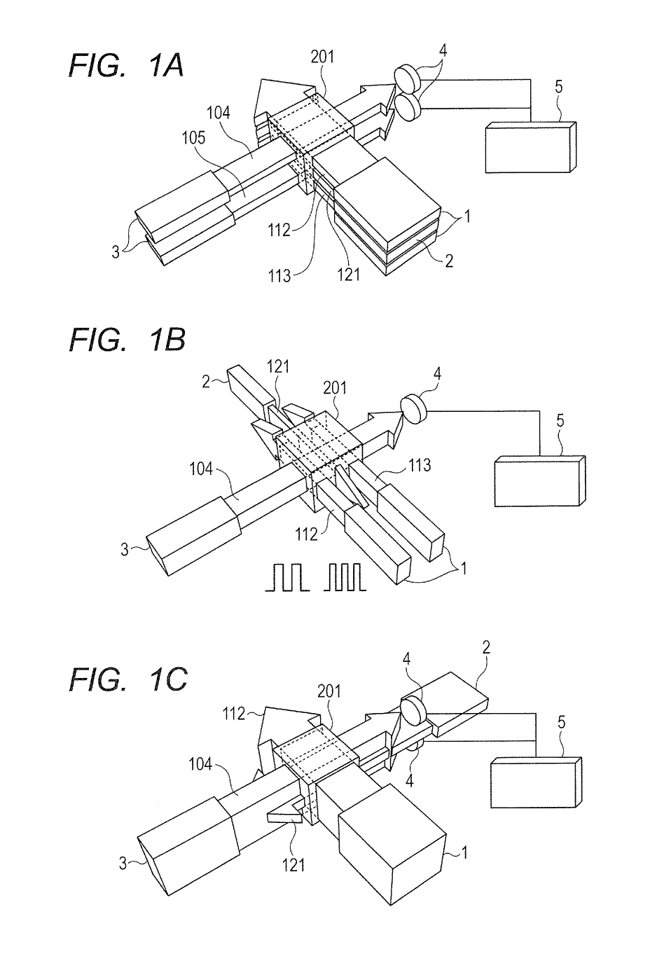

As one example of the optically pumped magnetometer, as illustrated in FIG. 1A, a configuration is available that uses two pump lights (112, 113) that are emitted from a pump light optical system 1, two probe lights (104, 105) that are emitted from a probe light optical system 3, and two detection units 4. That is, inside a cell 201, the first pump light 112 and the first probe light 104 intersect at a first measurement region, and the second pump light 113 and the second probe light 105 intersect at a second measurement region. The optically pumped magnetometer also includes first and second detection units 4 that detect the first and second probe lights (104, 105). Reference numeral 5 denotes an information acquisition unit.

Further, as another example, as illustrated in FIG. 1B, a configuration is available that uses two pump lights (112, 113), one probe light (104), and one detection unit 4. That is, inside the cell 201, a first pump light 112 that is modulated in accordance with a first modulation condition and the aforementioned probe light 104 intersect in a first measurement region, and a second pump light 113 that is modulated in accordance with a second modulation condition that is different from the first modulation condition and the probe light 104 intersect in a second measurement region, and the optically pumped magnetometer also includes the detection unit 4 that detects the probe light 104.

As a further example, as illustrated in FIG. 1C, a configuration is available that uses one pump light (112), one probe light (104) and two detection units 4. That is, this configuration includes first and second detection units 4 that detect the probe light 104 after passing through a first measurement region, and the probe light 104 after passing through a second measurement region.

Hereunder, an optically pumped magnetometer and a magnetic sensing method according to exemplary embodiments of the present invention are described in detail.

### First Embodiment

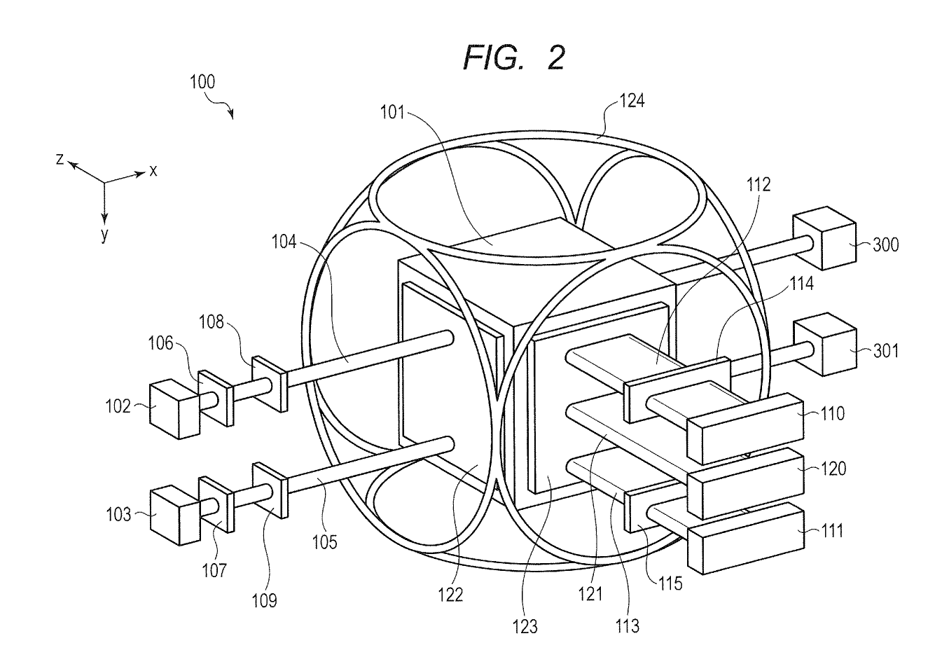

An optically pumped magnetometer and a magnetic sensing method according to a first embodiment of the present invention will now be described using FIGS. 2, 3 and 4.

FIG. 2 is a perspective view illustrating the configuration of an optically pumped magnetometer according to the present embodiment. First, a schematic configuration of the optically pumped magnetometer according to the present embodiment will be described using FIG. 2.

An optically pumped magnetometer 100 according to the present embodiment includes an isothermal insulating bath 101, probe light sources 102 and 103, linear light polarizers 106 and 107, half wavelength plates 108 and 109, pump light sources 110 and 111, quarter wavelength plates 114 and 115, a relaxing light source 120, polarization measurement systems 300 and 301, and a cell that is described later.

A cell which encapsulates alkali metal atoms, for example, potassium (K), is disposed inside the isothermal insulating bath 101. Optical windows 122 and 123 for introducing probe lights 104 and 105, pump lights 112 and 113, and relaxing light 121 into the isothermal insulating bath 101 are provided in the wall surface of the isothermal insulating bath 101. A bias magnetic field adjusting coil 124 is disposed around the isothermal insulating bath 101.

The probe light source 102 is configured so as to cause the probe light 104 having a linearly polarized light component to enter the cell in the isothermal insulating bath 101 via the linear light polarizer 106, the half wavelength plate 108 and the optical window 122. After passing though the cell, the probe light 104 is incident on the polarization measurement system 300 through an unshown optical window. The probe light source 103 is configured to cause the probe light 105 having a linearly polarized light component to enter the cell in the isothermal insulating bath 101 via the linear light polarizer 107, the half wavelength plate 109 and the optical window 122. After passing though the cell, the probe light 105 is incident on the polarization measurement system 301 through an unshown optical window. These probe light optical systems are arranged so that the probe lights 104 and 105 propagate through the inside of the cell in the isothermal insulating bath 101 along the x direction in the coordinate system shown in FIG. 2.

The pump light source 110 is configured to cause the pump light 112 to enter the cell in the isothermal insulating bath 101 via the quarter wavelength plate 114 and the optical window 123. The pump light source 111 is configured to cause the pump light 113 to enter the cell in the isothermal insulating bath 101 via the quarter wavelength plate 115 and the optical window 123.

After entering the cell, the pump light 112 which has a circularly polarized light component intersects with the probe light 104. Likewise, after entering the cell, the pump light 113 which has a circularly polarized light component intersects with the probe light 105. The pump light optical systems are arranged so that the pump lights 112 and 113 propagate through the inside of the cell in the isothermal insulating bath 101 along the z direction in the coordinate system shown in FIG. 2.

The relaxing light source 120 is configured to cause the relaxing light 121 to enter the cell in the isothermal insulating bath 101 through the optical window 123.

After entering the cell in the isothermal insulating bath 101, the relaxing light 121 passes through a region between an intersection region constituted by the probe light 104 and the pump light 112 and an intersection region constituted by the probe light 105 and the pump light 113. The relaxing light source 120 is arranged so that the relaxing light 121 propagates through the inside of the cell along the z direction in the coordinate system shown in FIG. 2.

The pump lights 112 and 113 and relaxing light 121 that have passed through the cell are subjected to a termination process inside the isothermal insulating bath 101. Alternatively, the pump lights 112 and 113 and relaxing light 121 may be subjected to a termination process by an optical terminator or the like after being emitted from the isothermal insulating bath through an optical window.

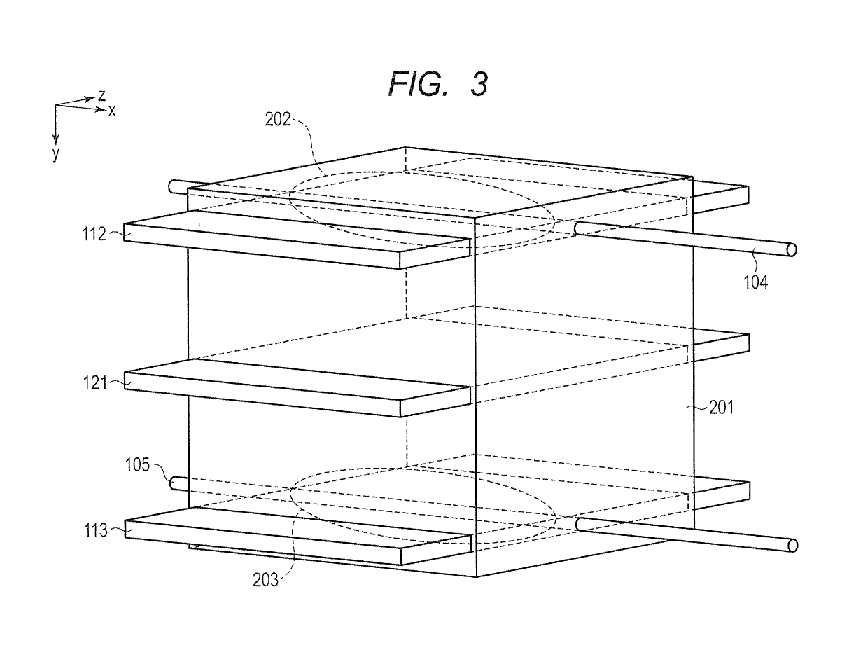

Next, fundamental operations of the optically pumped magnetometer according to the present embodiment will be described using FIG. 2 and FIG. 3. FIG. 3 is a detail drawing illustrating the manner in which, in the cell 201 that is disposed inside the isothermal insulating bath 101, the probe light 104 and the pump light 112 intersect at an intersection region 202, and the probe light 105 and the pump light 113 intersect at an intersection region 203.

The alkali metal atoms in the cell 201 are spin-polarized by the pump lights 112 and 113 entering the cell 201. A torque that is in accordance with the magnetic field to be measured induces precession of the spin polarization of the atoms. The motion of the spin polarization is described by the following Bloch equation (Equation (1)).

$$\frac{d \vec{S}}{d t} = D {∇}^{2} \vec{S} + \frac{γ}{q} \vec{S} \times \vec{B} + \frac{{R}_{op}}{q} ( \frac{s}{2} \vec{z} - \vec{S} ) - \frac{{R}_{relax}}{q} \vec{S} - \frac{{S}_{x} \vec{x} + {S}_{y} \vec{y}}{{T}_{2}} - \frac{{S}_{z} \vec{z}}{{T}_{1}} \qquad Equation ( 1 )$$

In Equation (1), a vector

\vec{s}(=(Sx, Sy, Sz)^{γ})

represents the spin of the alkali metal atoms. D represents the diffusion coefficient of the spin, γ represents the gyromagnetic ratio, and “q” represents the slowdown factor.

A vector

\vec{E}

represents an external magnetic field. Rₒₚ represents the optical pumping rate by pump light. “s” represents a circular polarization degree of pump light. Rᵣₑₗₐₓ represents a relaxation rate produced by relaxing light. T₁ represents a longitudinal relaxation time. T₂ represents a transversal relaxation time.

Vectors

\vec{x}, \vec{y}, \vec{z}

represent unit direction vectors. Note that the coordinate system uses the coordinates shown in FIG. 3. Here, a situation will be considered in which the pump light is introduced from the z direction.

A situation in which the pump light 112 which is in the shape of a thin flat plate enters in a travelling direction that is the z direction at a site at which y=0, and the pump light 113 which is in the shape of a thin flat plate enters in a travelling direction that is the z direction at a site at which y=“a” will now be considered. It may be considered that diffusion of the spin at this time is in only the y direction. Assuming that the relaxing light 121 is not radiated and the magnetic field of a measurement target is not applied, Equation (1) becomes the equation shown in Equation (2) with respect to S_{z}.

$$\frac{d {S}_{x}}{d t} = D \frac{{\partial }^{2} }{\partial {y}^{2}} {S}_{z} + \frac{{R}_{op} ( δ ( y ) + δ ( y - a ) )}{q} ( \frac{s}{2} - {S}_{z} ) - \frac{{S}_{z}}{{T}_{1}} \qquad Equation ( 2 )$$

Here, δ(y) is a δ function. Regarding the stationary solution relating to “t” in Equation (2), the solution where dS_{z}/dt=0 is as shown in Equation (3).

$${S}_{z} ( y ) = \frac{\frac{{R}_{op}}{4 q} \sqrt{\frac{{T}_{1}}{D}}}{1 + \frac{{R}_{op}}{2 q} \sqrt{\frac{{T}_{1}}{D}} ( 1 + Exp ( - \frac{a}{\sqrt{{DT}_{1}}} ) )} ( Exp ( - \frac{y}{\sqrt{{DT}_{1}}} ) + Exp ( \frac{y - a}{\sqrt{{DT}_{1}}} ) ) \qquad Equation ( 3 )$$

Thus, spin polarization generated by the pump light 112 creates spin polarization as far as a position outside the pump light irradiation region for which the distance is characterized by

\sqrt{DT₁}.

In a case where the diffusion coefficient D is potassium, the value thereof is 0.41 cm²/s in a standard state, and is 0.33 cm²/s in a situation of 180° C. and 1.6 atm. Since the longitudinal relaxation time T₁ is 100 ms, a diffusion length

\sqrt{DT₁}

is 0.18 cm.

Based on the spatial distribution of the spin polarization as above, if it is assumed that the magnetic field of the measurement target is applied, the response of the spin to the measuring magnetic field at the site of the intersection region 202 will be propagated by the polarized spatial distribution and detected with the probe light 105 at the site of the intersection region intersection region 203.

The relaxing light 121 emitted from the relaxing light source 120 is light for causing the spin polarization of alkali metal atoms that are present between the intersection region 202 and the intersection region 203 in the cell 201 to quickly relax to reduce mixing of signals caused by spatial distribution of the spin polarization.

The relaxing light 121 emitted from the relaxing light source 120 has a wavelength that is a D1 transition resonance wavelength or a D2 transition resonance wavelength, and has an action that, through light absorption, weakens (T1 relaxation) or relaxes the phase (T2 relaxation) of spin polarization by exciting alkali metal atoms that were spin-polarized in the cell 201.

There are two kinds of light that do not function as relaxing light. One kind is circularly polarized light that propagates in the same direction as the pump light and rotates in the same direction, and the other kind is circularly polarized light that propagates in the reverse direction to the pump light and rotates in the reverse direction.

Light other than the two kinds described above has a function as relaxing light. Specifically, such lights are: A) unpolarized light; B) linearly polarized light (regardless of the plane of polarization); C) circularly polarized light that propagates in the same direction as the pump light and rotates in the reverse direction; D) circularly polarized light that propagates in the reverse direction to the pump light and rotates in the same direction; and E) circularly polarized light in an arbitrary direction that propagates in a different direction to the pump light. Since each of these kinds of light excite electrons in both spin states, these kinds of light have a function that relaxes spin polarization that was created by pump light. Since the lights described in A) to D) above cause spin polarization to relax without generating new spin polarization, these lights are suitable for use as relaxing light in the present embodiment. The light described in E) generates new spin polarization and rotation of the plane of polarization of the probe light occurs as a result of rotation of the spin polarization under the magnetic field or directly. Therefore the light described in E) is not suitable as relaxing light to be used in the optically pumped magnetometer of the present embodiment.

In the case of the optically pumped magnetometer exemplified in FIG. 1A, the above described A) unpolarized light, B) linearly polarized light (regardless of the plane of polarization), or C) circularly polarized light that propagates in the same direction as the pump light and rotates in the reverse direction is used as the relaxing light. In the case of the optically pumped magnetometer exemplified in FIG. 1B, the above described A) unpolarized light, B) linearly polarized light (regardless of the plane of polarization), or D) circularly polarized light that propagates in the reverse direction to the pump light and rotates in the same direction is used as the relaxing light. Further, in the case of the optically pumped magnetometer exemplified in FIG. 1C, the relaxing light may be the above described A) unpolarized light or B) linearly polarized light (regardless of the plane of polarization).

Note that, Japanese Patent Application Laid-Open No. 2012-159402 discloses a magnetic field measurement apparatus which includes a unit that radiates light (induction light) that stimulates photo-stimulated desorption of atoms in a cell, and the aforementioned apparatus is common with the exemplary embodiments of the invention of the present application only in the respect that, in addition to the pump light and probe light, a third light is also radiated at a cell. However, an object of the induction light described in Japanese Patent Application Laid-Open No. 2012-159402 is to stimulate photo-stimulated desorption of atoms in a cell, and it is desirable that light radiated in accompaniment therewith is light having a high level of optical energy, with ultraviolet light being mentioned as an example. In contrast, the relaxing light in the exemplary embodiments of the invention of the present application is light for quickly relaxing the spin polarization of alkali metal atoms, and the light has a wavelength that is the D1 transition resonance wavelength or D2 transition resonance wavelength of alkali metal atoms in the cell. Further, light having a wavelength in the ultraviolet region may not be included among the relaxing light in the exemplary embodiments of the invention of the present application, and a range of wavelengths of the relaxing light can be between 700 nm and 900 nm.

The plane of polarization of the probe light 104 that passed through the intersection region 202 is subjected to a paramagnetic Faraday rotation that is proportional to a spin polarization Sₓ^{a} of the intersection region 202. Subsequently, the probe light 104 enters the polarization measurement system 300 and undergoes polarization measurement. The plane of polarization of the probe light 105 that passed through the intersection region 203 is subjected to a paramagnetic Faraday rotation that is proportional to a spin polarization Sₓ^{b} of the intersection region 203. Subsequently, the probe light 105 enters the polarization measurement system 301 and undergoes polarization measurement. As a result, a magnetic field component “B_{y}” in the y direction in FIG. 2 at each intersection region is measured.

Next, an example of the optically pumped magnetometer 100 according to the present embodiment will be more specifically described with regard to the respective constituent parts thereof.

{1} Isothermal Insulating Bath 101

A glass cell is disposed in the isothermal insulating bath 101. The cell is an airtight structure made of a material, such as glass, that is transparent with respect to the probe light and the pump light. Potassium (K) as alkali metal atoms is encapsulated in the cell. Other than potassium, examples of the alkali metal atoms that can be utilized for the cell include rubidium (Rb) and cesium (Cs). The alkali metal atoms encapsulated in the cell need not necessarily be of one type, and at least one type of atom selected from the group consisting of potassium, rubidium and cesium can be included.

A buffer gas and a quencher gas are also enclosed in the cell. Helium (He) gas may be mentioned as an example of the buffer gas. Helium gas has an effect of reducing diffusion of polarized alkali metal atoms and is effective for increasing the polarization rate by suppressing spin relaxation caused by collision with a cell wall. Nitrogen (N₂) gas may be mentioned as an example of the quencher gas. Nitrogen gas is a quencher gas for reducing fluorescence by taking away energy from potassium atoms in an excited state and is effective for increasing the efficiency of optical pumping.

The scattering cross section of potassium atoms with respect to spin polarization destruction caused by collision between the potassium atoms themselves and collision of the potassium atoms with helium atoms is the smallest among the alkali metal atoms. Note that, the scattering cross section of rubidium atoms with respect to spin polarization destruction is the next smallest after the potassium atoms. Therefore, potassium can be used as the alkali metal atoms for constructing a magnetic sensor with a long relaxation time and a large magnetic field signal response.

On the other hand, vapor pressures of rubidium and cesium are higher than that of potassium under the same temperature, and therefore an advantage of using rubidium or cesium is that the same atom density can be obtained at a lower temperature in comparison to potassium. Therefore, using rubidium atoms or cesium atoms is also effective from the viewpoint of constructing a sensor that operates at a lower temperature.

At the time of measurement, the cell is heated to a temperature of a maximum of about 200° C. to increase the density of the alkali metal gas in the cell. The isothermal insulating bath 101 plays a role of preventing the heat from escaping to outside.

A system that heats the cell by pouring a heated inert gas into the isothermal insulating bath 101 from the outside may be mentioned as an example of the system for heating the cell in the isothermal insulating bath 101. Alternatively, a system may be adopted that applies a current to a heater arranged in the isothermal insulating bath 101 to heat the cell. In this case, driving the heater by means of a current with a frequency that is twice or more higher than the modulation frequency of the pump light is effective for preventing the magnetic field caused by the heater current from affecting the measurement signal. Further, the system for heating the cell may be an optical heating system in which the cell or a light absorption member arranged around the cell absorbs light introduced from outside of the isothermal insulating bath 101 to thereby heat the cell 201.

{2} Bias Magnetic Field Adjusting Coil 124

The bias magnetic field adjusting coil 124 is installed inside a magnetic shield that is not illustrated in the drawings. The magnetic shield is provided in order to reduce a magnetic field entering from the external environment.

The bias magnetic field adjusting coil 124 is used to control the magnetic field environment around the cell in the isothermal insulating bath 101. A triaxial Helmholtz coil may be mentioned as a specific example of the bias magnetic field adjusting coil 124. Specifically, the bias magnetic field adjusting coil 124 applies a bias magnetic field in a direction (z direction in the drawings) parallel to the pump light 112 so that the measuring frequency and the Larmor frequency coincide and resonate.

The bias magnetic field adjusting coil 124 is used to make the environment one in which residual magnetic fields (in the x direction and y direction in the drawings) in directions other than the bias magnetic field direction are cancelled out, and a magnetic field is not applied other than in the bias magnetic field direction. Shim coils may also be added to correct spatial inhomogeneity of the magnetic field.

{3} Probe Light Optical System

The probe light optical system includes the probe light sources 102 and 103, the linear light polarizers 106 and 107, and the half wavelength plates 108 and 109.

The wavelength of the probe light 104 emitted from the probe light source 102 and the probe light 105 emitted from the probe light source 103 is detuned by about several GHz to several dozen GHz from an optical frequency corresponding to the D1 transition resonance wavelength of the alkali metal atoms so as to maximize the signal response. The detuning value for maximizing the signal response depends on the pressure and temperature of the buffer gas pressure in the cell in the isothermal insulating bath 101. The probe light sources 102 and 103 may include a stabilization unit, such as an external resonator, to stably maintain the wavelength. The linear light polarizer 106 forms the probe light 104 into linearly polarized light. The linear light polarizer 107 forms the probe light 105 into linearly polarized light. With regard to the selection criterion for the wavelength, the detuning may be selected based on the condition of maximizing the SNR. Regardless of which criterion is used, the optimal amount of detuning depends on the pump light intensity in the cell. Therefore, it is also effective to periodically perform calibration during the measurement to correct the amount of detuning.

{4} Pump Light Optical System

As illustrated in FIG. 2, the pump light optical system includes the pump light sources 110 and 111 and the quarter wavelength plates 114 and 115.

The polarized light of the pump light 112 emitted from the pump light source 110 and the pump light 113 emitted from the pump light source 111 are linearly polarized light, and the wavelength of each of these lights is adjusted to the D1 transition resonance wavelength of the alkali metal atoms and, in practice, wavelengths within a range of about 1 to 10 nm from the D1 transition resonance wavelength can be included. The pump light sources 110 and 111 include an optical frequency stabilization unit for fixing the wavelength of the respective pump lights to the D1 transition resonance wavelength of the alkali metal atoms in the cell. The pump light 112 is converted into circularly polarized light by the quarter wavelength plate 114, and the pump light 113 is converted into circularly polarized light by the quarter wavelength plate 115. At such time, the pump lights 112 and 113 may be converted to either one of clockwise circularly polarized light and counter-clockwise circularly polarized light.

The pump lights 112 and 113 which are polarized in the form of circularly polarized light enter the cell in the isothermal insulating bath 101, and polarize alkali metal atom groups on the optical paths of the pump lights 112 and 113 in the cell.

Further, as the pump light optical system, a configuration can also be utilized in which light from the same pump light source is split by a beam splitter or the like into the pump lights 112 and 113 which are then used to spin-polarize the alkali metal atoms.

{5} Relaxing Light 121

The wavelength of the relaxing light 121 emitted from the relaxing light source 120 is the D1 transition resonance wavelength or D2 transition resonance wavelength of the alkali metal atoms and, in practice, wavelengths within a range of about 1 to 10 nm from these transition resonance wavelengths can be included.

The relaxing light source 120 includes a frequency stabilization unit for fixing the wavelength of the relaxing light 121 to the D1 transition resonance wavelength or D2 transition resonance wavelength of the alkali metal atoms.

As one example of the present embodiment, the relaxing light source 120 includes an optical frequency stabilization unit for fixing the wavelength of the relaxing light 121 to the D1 transition resonance wavelength (range of 770.1 nm±10 nm) of potassium atoms or to the D2 transition resonance wavelength (range of 766.7 nm±10 nm) of potassium atoms. Alternatively, in a case where the alkali metal atoms in the cell are rubidium, the wavelength of the relaxing light 121 is fixed to the D1 transition resonance wavelength (range of 795.0 nm±10 nm) of rubidium atoms or to the D2 transition resonance wavelength (range of 780.2 nm±10 nm) of rubidium atoms. Likewise, in a case where the alkali metal atoms in the cell are cesium, the wavelength of the relaxing light 121 is fixed to the D1 transition resonance wavelength (range of 894.6 nm±10 nm) of cesium atoms or to the D2 transition resonance wavelength (range of 852.3 nm±10 nm) of cesium atoms. In addition, in a case where the intensity of relaxing light is sufficient, the wavelength of the relaxing light 121 may be detuned somewhat from the transition resonance wavelength.

The relaxing light 121 passes through the optical window 123 and enters the cell in the isothermal insulating bath 101, and is absorbed by alkali metal atom groups on the optical path of the relaxing light 121 in the cell. Linearly polarized light can be used as the polarized light of the relaxing light 121, as use thereof most efficiently relaxes spin polarization. In the case of linearly polarized light, the absorption rate of light is constant regardless of the direction of spin polarization, and because excited alkali metal atoms transition almost uniformly to two ground levels due to spontaneous de-excitation or collisional de-excitation caused by collision with quencher gas atoms or the like, the spin polarization is relaxed.

The relaxing light 121 may pass through any part of a region between the intersection region 202 constituted by the probe light 104 and the pump light 112 and the intersection region 203 constituted by the probe light 105 and the pump light 113. In the exemplary embodiments, the entry direction is, for example, the −z direction, z direction, −x direction or x direction, and the entry position may be somewhat up or down (for example, in the y direction). Further, the number of intersection regions is not limited to two, and three or more intersection regions may be formed. In that case, mixing of spin polarization can be prevented by radiating relaxing light between each intersection region.

In the case of utilizing unpolarized light as polarization of the relaxing light 121, it is necessary to prepare light in which the oscillating direction of the electric field is, as much as possible, temporally random, and on average the circular polarization degree is 0. Further, in a case where circularly polarized light that propagates in the same direction as the pump light and rotates in the reverse direction thereto is utilized as the relaxing light 121, or circularly polarized light that propagates in the opposite direction to the pump light and rotates in the same direction thereto is utilized as the relaxing light 121, it is necessary to appropriately adjust the intensity of the relaxing light so as not to generate a new spin polarization.

{6} Polarization Measurement Systems 300 and 301

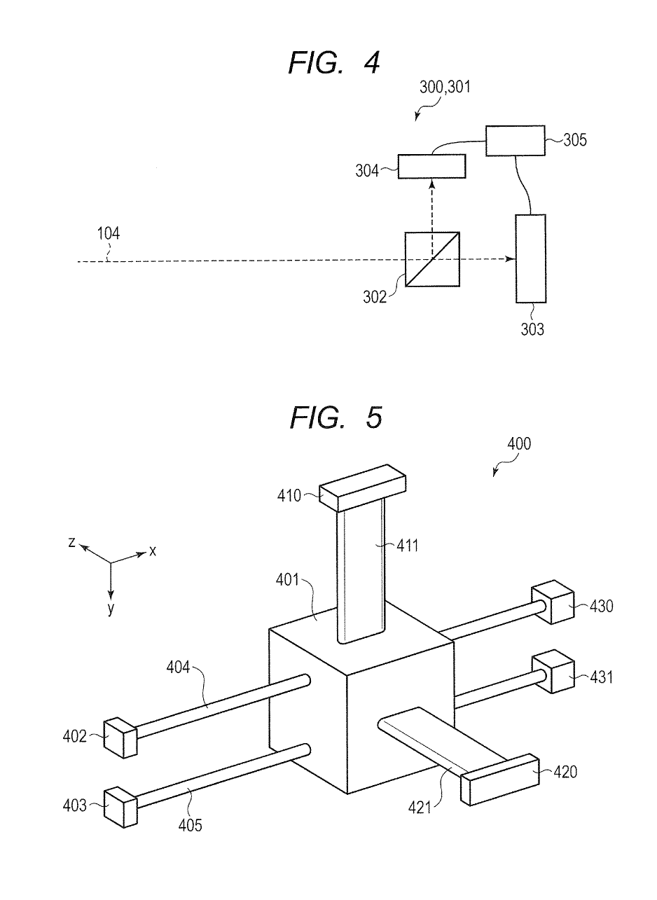

As illustrated in FIG. 4, the polarization measurement system 300 includes a polarization splitter 302, photodetectors 303 and 304, and a differential circuit 305. Since the polarization measurement system 301 has a similar configuration to the polarization measurement system 300, the configuration of the polarization measurement system 300 will be used in the following description.

The probe light 104 entering the polarization splitter 302 is split into transmitted light and reflected light in accordance with a polarization angle θ. In terms of the ratio of light power, the intensity ratio between the transmitted light and the reflected light is cos² θ:sin² θ. This is based on a polarized state in which all of the light entering the polarization splitter 302 passes therethrough and enters the photodetector 303, that is, a case where θ=0°. In this case, all of the light at θ=90° is reflected and enters the photodetector 304.

The photodetectors 303 and 304 measure the power intensities of the lights obtained by splitting the probe light 104 in two, and the difference therebetween is output from the differential circuit 305. When the polarization of the probe light 104 at a time when a magnetic field to be measured is not present is adjusted to θ=45°, lights with the same light power enter the photodetectors 303 and 304 when there is no magnetic field to be measured, and the output from the differential circuit 305 is 0.

On the other hand, when there is a magnetic field to be measured, rotation of the plane of polarization occurs that is in accordance with the size of the magnetic field to be measured. Consequently, lights with different light powers to each other enter the photodetectors 303 and 304, and a difference therebetween that is not 0 is output from the differential circuit 305. That is, the output from the differential circuit 305 at this time is a signal proportional to the rotation angle of the plane of polarization of the probe light 104, and is a signal that reflects the size of the magnetic field to be measured.

Thus, according to the present embodiment, by radiating relaxing light between a plurality of measurement regions, mixing of spin polarization can be prevented, the accuracy of separating spatially different magnetic signals can be increased, and the magnetic signals can be simultaneously measured.

### Second Embodiment

An optically pumped magnetometer and a magnetic sensing method according to a second embodiment of the present invention will now be described using FIG. 5. Hereunder, the same constituent elements as in the optically pumped atomic magnetometer according to the first embodiment illustrated in FIG. 2 and FIG. 4 are referred to by the same names, and a description of these constituent elements will be omitted or simplified. The description of the same constituent elements in the respective exemplary embodiments can be applied to each thereof within a range that is not contrary to the configurations specific to the respective exemplary embodiments.

FIG. 5 is a perspective view illustrating a schematic configuration of the optically pumped magnetometer according to the present embodiment.

As illustrated in FIG. 5, an optically pumped magnetometer 400 according to the present embodiment includes an isothermal insulating bath 401, probe light optical systems 402 and 403, a pump light optical system 410, a relaxing light optical system 420 and polarization measurement systems 430 and 431.

A probe light 404 enters the polarization measurement system 430, a probe light 405 enters the polarization measurement system 431, and the polarization of the probe light 404 and the probe light 405 is measured.

The configuration and operation of the optically pumped magnetometer according to the present embodiment are the same as those of the optically pumped magnetometer of the first embodiment that is illustrated in FIG. 2 and FIG. 4 with regard to the isothermal insulating bath, the bias magnetic field adjusting coil, the probe light optical systems and the polarization measurement systems.

Next, portions of the optically pumped magnetometer 400 according to the present embodiment that constitute the pump light optical system 410 and the relaxing light optical system 420 are described.

{1} Pump Light Optical System 410

Polarized light of a pump light 411 that is emitted from the pump light optical system 410 is circularly polarized light, and the wavelength thereof is adjusted to the D1 transition resonance wavelength of the alkali metal atoms. The pump light optical system 410 includes an optical frequency stabilization unit for fixing the wavelength of the pump light to the D1 transition resonance wavelength of the alkali metal atoms.

When the pump light 411 that has a circularly polarized light component enters the cell, firstly, the pump light 411 intersects with the probe light 404 and polarizes alkali metal atom groups in the intersection region. The pump light optical system 410 is arranged so that, with respect to the coordinate system illustrated in FIG. 5, the pump light 411 propagates through the inside of the cell in the isothermal insulating bath 401 along the y direction. Thereafter, the pump light 411 polarizes alkali metal atom groups in the intersection region with the probe light 405. Thus, the configuration is such that a single pump light intersects with a plurality of probe lights and polarizes alkali metal atom groups in each intersection region.

{2} Relaxing Light Optical System 420

The wavelength of a relaxing light 421 that is emitted from the relaxing light optical system 420 is adjusted to the D1 transition resonance wavelength of the alkali metal atoms. As one example of the present embodiment, the relaxing light optical system 420 includes an optical frequency stabilization unit for fixing the wavelength of the relaxing light 421 to the D1 transition resonance wavelength (770.1 nm) of potassium atoms. Alternatively, the wavelength of the relaxing light 421 may be fixed to the D2 transition resonance wavelength (766.7 nm) of potassium atoms.

The relaxing light 421 passes through an unshown optical window to enter the cell inside the isothermal insulating bath 401, and relaxes the spin polarization of alkali metal atom groups on the optical path of the relaxing light 421 in the cell. The relaxing light 421 may pass through any part of a region between the intersection region constituted by the probe light 404 and the pump light 411 and the intersection region constituted by the probe light 405 and the pump light 411. The entry position thereof may be somewhat up or down in the y direction, and the entry direction may be the −z direction or a direction parallel to that of the probe light, that is, the relaxing light 421 may enter from the x direction or the −x direction. Further, the number of probe lights intersecting with the pump light 411 is not limited to two, and three or more probe lights may be caused to intersect therewith. In this case, mixing of spin polarization can be prevented by radiating the relaxing light between each intersection region.

Thus, according to the present embodiment, in a configuration in which alkali metal atom groups at intersection regions with a plurality of probe lights are polarized in the y direction in FIG. 5 by a single pump light, and the magnetic fields of z-direction components are measured, mixing of spin polarization can be prevented by radiating relaxing light between the plurality of intersection regions and the accuracy of separating spatially different magnetic signals can be improved. Further, measurement can be performed simultaneously.

### Third Embodiment

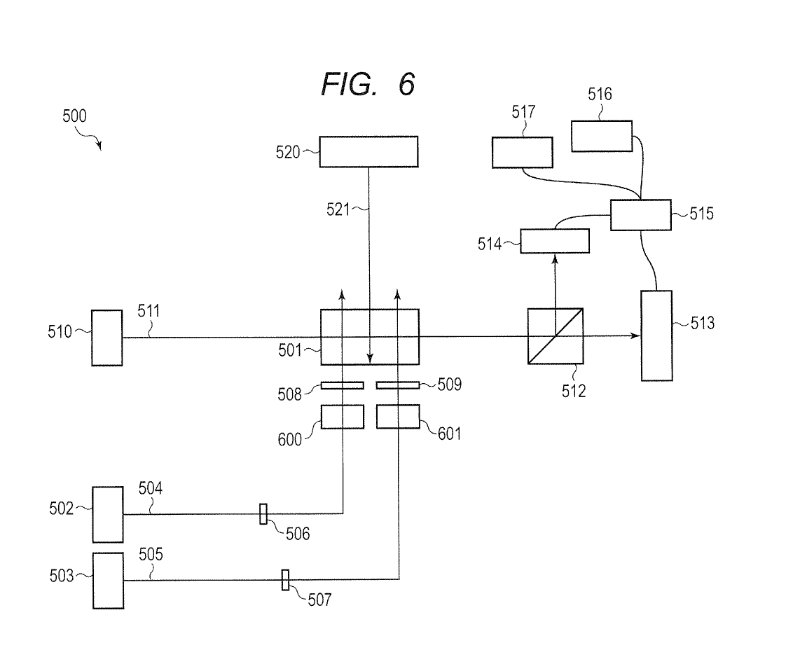

An optically pumped magnetometer and a magnetic sensing method according to a third embodiment of the present invention will now be described using FIG. 6.

FIG. 6 is a schematic diagram illustrating the configuration of the optically pumped magnetometer according to the present embodiment.

As illustrated in FIG. 6, an optically pumped magnetometer 500 according to the present embodiment includes an isothermal insulating bath 501, pump light sources 502 and 503, linear light polarizers 506 and 507, optical modulation portions 600 and 601, quarter wavelength plates 508 and 509, a probe light optical system 510, a relaxing light optical system 520, a polarization splitter 512, photodetectors 513 and 514, a differential circuit 515 and demodulators 516 and 517.

The configuration and operation of the optically pumped magnetometer according to the present embodiment are the same as those of the optically pumped magnetometer according to the second embodiment that is illustrated in FIG. 5 with regard to the isothermal insulating bath, the bias magnetic field adjusting coil, the probe light optical system and the relaxing light optical system.

A probe light 511 is split by the polarization splitter 512 into reflected light and transmitted light according to the intensity thereof in accordance with the angle of the plane of polarization thereof. The transmitted light from the polarization splitter 512 enters the photodetector 513, and the reflected light from the polarization splitter 512 enters the photodetector 514. The differential circuit 515 is connected to the photodetectors 513 and 514.

Next, the respective constituent portions of the optically pumped magnetometer 500 according to the present embodiment are described specifically.

{1} Pump Light Optical System

As illustrated in FIG. 6, the pump light optical system includes the pump light sources 502 and 503, the linear light polarizers 506 and 507, the optical modulation portions 600 and 601, and the quarter wavelength plates 508 and 509.

The respective wavelengths of a pump light 504 emitted from the pump light source 502 and a pump light 505 emitted from the pump light source 503 are fixed to the D1 transition resonance wavelength of the alkali metal atoms by an optical frequency stabilization unit included in the pump light sources 502 and 503. The pump light 504 is adjusted to linearly polarized light by the linear light polarizer 506, and is thereafter subjected to modulation by the optical modulation portion 600 and adjusted to circularly polarized light by the quarter wavelength plate 508. The pump light 505 is adjusted to linearly polarized light by the linear light polarizer 507, and is thereafter subjected to modulation by the optical modulation portion 601 and adjusted to circularly polarized light by the quarter wavelength plate 509. The pump lights 504 and 505 that enter the cell in the isothermal insulating bath 501 polarize groups consisting of alkali metal atoms on the optical paths thereof, respectively. Light from the same light source that is split by a beam splitter or the like may also be utilized as the pump lights 504 and 505.

{1.1} Light Modulation System (Optical Modulation Portions 600 and 601)

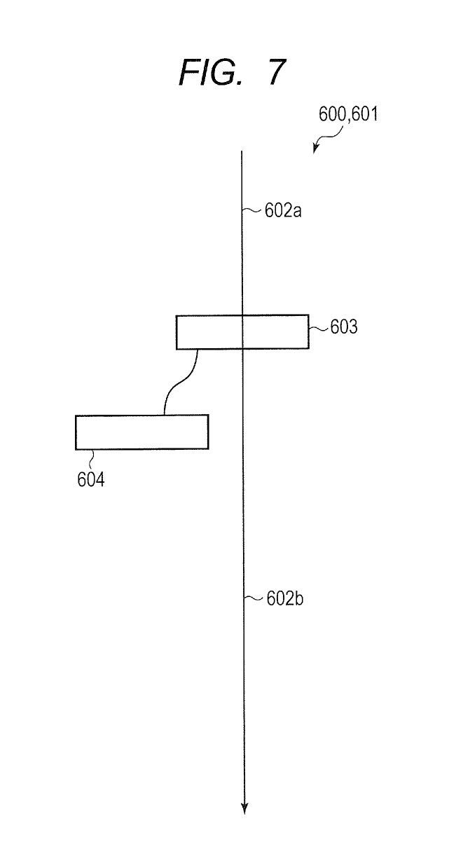

The pump light 504 is subjected to modulation by the optical modulation portion 600 to the pumping rate thereof. The pump light 505 is subjected to modulation by the optical modulation portion 601 to the pumping rate thereof. Pump light intensity modulation may be mentioned as an example of the modulation method in the optical modulation portions 600 and 601. A specific configuration of the optical modulation portions 600 and 601 is described hereinafter using FIG. 7. A method that utilizes an optical chopper may be mentioned as an example of the pump light intensity modulation. The optical chopper is a component that periodically interrupts the light, and the light intensity of the light passing through the optical chopper is modulated by a rectangular wave. That is, as illustrated in FIG. 7, by introducing a pump light 602a into the optical chopper 603, a pump light 602b can be obtained in which the light intensity is modulated in a rectangular wave shape. A signal generator 604 for controlling the optical chopper 603 can control the modulation frequency of the optical chopper 603. Optical frequency modulation and circular polarization degree modulation are conceivable as other modulation methods.

The number of pump lights intersecting with a probe light is not limited to two, and a pump light having a different modulation frequency to each of the probe lights may be caused to intersect with three or more probe lights.

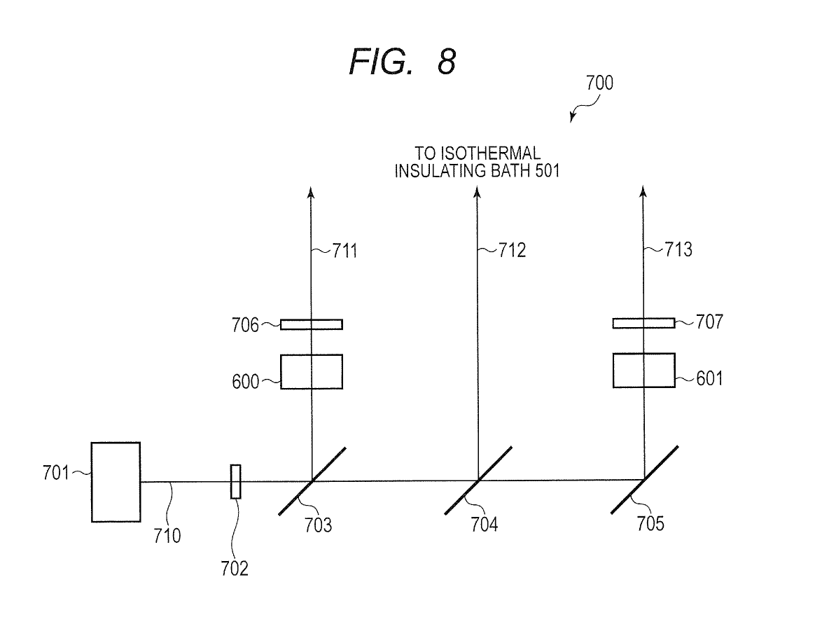

A configuration is also possible in which the same light source is utilized for the pump light optical system and the relaxing light optical system, as illustrated in FIG. 8. A composite pump light and relaxing light optical system 700 illustrated in FIG. 8 includes a light source 701, a linear light polarizer 702, optical beam splitters 703 and 704, a mirror 705, optical modulation portions 600 and 601, and quarter wavelength plates 706 and 707.

The wavelength of a laser beam 710 that is emitted from the light source 701 is fixed to the D1 transition resonance wavelength of alkali metal atoms by an optical frequency stabilization unit included in the light source 701. The laser beam 710 is adjusted so as to become linearly polarized light by the linear light polarizer 702, and thereafter a part thereof is separated as a pump light 711 by the optical beam splitter 703. The pump light 711 is subjected to modulation by the optical modulation portion 600, is adjusted into circularly polarized light by the quarter wavelength plate 706, and enters the isothermal insulating bath 501. On the other hand, a part of the laser beam 710 from which the part was separated by the optical beam splitter 703 is further separated therefrom as a relaxing light 712 by the optical beam splitter 704. The relaxing light 712 enters the isothermal insulating bath 501. The laser beam 710 from which the part was separated by the optical beam splitter 704 is radiated at the optical modulation portion 601 by the mirror 705. This light is referred to as “pump light 713”. The pump light 713 is subjected to modulation by the optical modulation portion 601, is adjusted into circularly polarized light by the quarter wavelength plate 707, and enters the isothermal insulating bath 501.

Components that separate incoming light into reflected light and transmitted light, such as a half-mirror or a beam splitter are used as the optical beam splitters 703 and 704. At such time, a polarized beam splitter for which the intensity ratio between the reflected light and transmitted light depends on the polarized light or the like may be used, and the polarized beam splitter may be combined with a half-wave plate to be thereby given a function that adjusts the intensity of the pump lights 711 and 713 and the relaxing light 712.

{2} Polarization Measurement System

As illustrated in FIG. 6, the polarization measurement system includes the polarization splitter 512, the photodetectors 513 and 514, the differential circuit 515, and the demodulators 516 and 517.

The output signal of the differential circuit 515 is input to and demodulated by the demodulators 516 and 517. A lock-in amplifier may be mentioned as an example of the demodulators. At such time, the demodulator 516 can demodulate the signal at the same frequency as the modulation frequency of the optical modulation portion 600 to thereby extract a magnetic signal of an intersection region between the probe light 511 and the pump light 504. Further, the demodulator 517 can demodulate the signal at the same frequency as the modulation frequency of the optical modulation portion 601 to thereby extract a magnetic signal of an intersection region between the probe light 511 and the pump light 505.

Thus, according to the present embodiment, by radiating relaxing light between a plurality of measurement regions, mixing of spin polarization is prevented, and the accuracy of separating spatially different magnetic signals on the optical path of the probe light 511 can be improved and the signals can be measured simultaneously.

### Fourth Embodiment

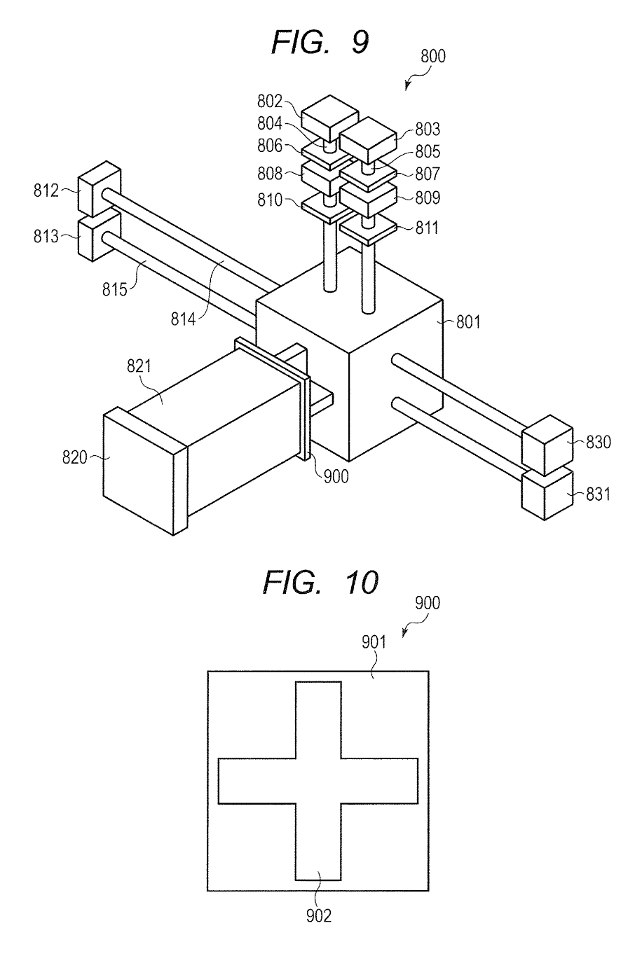

An optically pumped magnetometer and a magnetic sensing method according to a fourth embodiment of the present invention will now be described using FIG. 9.

FIG. 9 is a schematic diagram illustrating the configuration of the optically pumped magnetometer according to the present embodiment.

As illustrated in FIG. 9, an optically pumped magnetometer 800 according to the present embodiment includes an isothermal insulating bath 801, pump light sources 802 and 803, linear light polarizers 806 and 807, optical modulation portions 808 and 809, quarter wavelength plates 810 and 811, probe light optical systems 812 and 813, a relaxing light optical system 820, a relaxing light shaping unit 900, and polarization measurement systems 830 and 831.

The configuration and operation of the optically pumped magnetometer according to the present embodiment are the same as those of the optically pumped magnetometer according to the third embodiment that is illustrated in FIG. 6 with regard to the isothermal insulating bath, the bias magnetic field adjusting coil, the probe light optical system and the pump light optical system.

Next, the respective constituent portions of the optically pumped magnetometer 800 according to the present embodiment are described specifically.

{1} Relaxing Light Optical System 820

Polarized light of a relaxing light 821 that is emitted from the relaxing light optical system 820 is linearly polarized light, and the wavelength thereof is fixed to the D1 transition resonance wavelength or D2 transition resonance wavelength of alkali metal atoms by an optical frequency stabilization unit included in the relaxing light optical system 820. The relaxing light 821 is expanded by a beam expansion unit included in the relaxing light optical system 820 and radiated at the relaxing light shaping unit 900, and only a part thereof is cut out. The relaxing light 821 that has been cut out by the relaxing light shaping unit 900 enters a cell in the isothermal insulating bath 801, and is radiated into a region between probe lights 814 and 815 and a region between pump lights 804 and 805, and relaxes the polarization of alkali metal atom groups on the respective optical paths thereof.

{1.1} Relaxing Light Shaping Unit 900

Only a part of the beam of the relaxing light 821 is cut out by the relaxing light shaping unit 900. A specific configuration of the relaxing light shaping unit 900 is described hereunder using FIG. 10. The relaxing light shaping unit 900 includes a relaxing light blocking portion 901 and a relaxing light transmitting portion 902. The relaxing light blocking portion 901 is made of a material having a function that absorbs or reflects light of the wavelength of the relaxing light 821, and a part thereof is cut off so that the relaxing light 821 passes through the region between the probe lights 814 and 815 and the region between the pump lights 804 and 805. The relaxing light transmitting portion 902 is a portion that has a function of transmitting light of the wavelength of the relaxing light 821. Alternatively, the relaxing light transmitting portion 902 may be a slit in the relaxing light blocking portion 901. It is not necessary for only one relaxing light shaping unit 900 to be provided, and a plurality of the relaxing light shaping units 900 may be provided. In this case, the functions may be separated so that a first unit shapes the relaxing light 821 so as to be radiated into the region between the pump lights 804 and 805, and a second unit shapes the relaxing light 821 so as to be radiated into the region between the probe lights 814 and 815.

Further, the number of sets of pump lights and probe lights is not limited to two of each, and there may be three or more sets of each. In such a case, the relaxing light shaping unit 900 is constituted by the relaxing light blocking portion 901 and the relaxing light transmitting portion 902 that are arranged so that the relaxing light 821 is radiated into each region between the probe lights and each region between the pump lights.

### Fifth Embodiment

A fifth embodiment of the present invention is a method for acquiring information relating to magnetic field intensity, that is based on the above described exemplary embodiments. That is, there is provided a method for acquiring information relating to a magnetic field intensity of a region in a single cell that encapsulates alkali metal atoms, wherein: a region at which a pump light having a circularly polarized light component and a probe light having a linearly polarized light component are radiated and caused to intersect in the measurement region is taken as an intersection region; information relating to a magnetic field intensity of the intersection region is acquired by detecting the probe light that passes through the intersection region; and two or more of the intersection regions are provided, and a relaxing light is further radiated into the cell to relax spin polarization of alkali metal atoms that are present between two or more of the intersection regions. Specifically, the method includes at least the following three steps.
(1) A step of radiating a pump light having a circularly polarized light component and a probe light having a linearly polarized light component so as to cause the pump light and the probe light to intersect at a plurality of measurement regions;
(2) A step of acquiring information relating to a magnetic field intensity of the plurality of measurement regions by detecting the probe light that passes through the plurality of measurement regions; and
(3) A step of radiating a relaxing light into a cell to relax spin polarization of alkali metal atoms that are present between the plurality of measurement regions.

Note that, the method for acquiring information relating to a magnetic field intensity according to the present embodiment may also appropriately include steps other than the steps described above.

### Sixth Embodiment

An optically pumped magnetometer according to a sixth embodiment of the present invention is an optically pumped magnetometer that acquires information relating to a magnetic field intensity of an intersection region inside a single cell that encapsulates alkali metal atoms by causing a pump light having a circularly polarized light component and a probe light having a linearly polarized light component to intersect at the intersection region, and detecting the probe light after passing through the intersection region. The optically pumped magnetometer includes a relaxing light optical system that radiates a relaxing light that relaxes spin polarization of alkali metal atoms that are present in the intersection region inside the cell and takes one part of the intersection region as a measurement region. The area of a region delimited by the relaxing light can be changed by changing a position from which the relaxing light is radiated into the cell. That is, the volume of a region that the intersection region includes can be changed by changing a radiation position of the relaxing light.

### Modified Exemplary Embodiments

The present invention is not limited to the above described exemplary embodiments, and various modifications are possible.

The above described exemplary embodiments merely illustrate several modes that can apply the present invention, and do not prevent appropriate corrections and modifications being made within a range that does not deviate from the scope of the present invention.

According to the present invention, by radiating relaxing light between a plurality of measurement regions constituted by a pump light and a probe light, mixing of spin polarization can be prevented and the accuracy of separating spatially different magnetic signals can be improved.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2015-143660, filed Jul. 21, 2015, which is hereby incorporated by reference herein in its entirety.

What is claimed is:

1. An optically pumped magnetometer that acquires information relating to a magnetic field intensity of a first measurement region and a second measurement region inside a single cell encapsulating alkali metal atoms by causing a pump light having a circularly polarized light component and a probe light having a linearly polarized light component to intersect at the first and second measurement regions, and detecting the probe light after passing through the first and second measurement regions, comprising:
a relaxing light optical system that emits a relaxing light that relaxes spin polarization of alkali metal atoms that are present between the first and second measurement regions.

2. The optically pumped magnetometer according to claim 1, further comprising a first detection unit and a second detection unit that detect the probe light after passing through the first measurement region and the probe light after passing through the second measurement region, respectively.

3. The optically pumped magnetometer according to claim 1, wherein:
in the first measurement region, a first pump light which is modulated according to a first modulation condition and the probe light intersect inside the cell, and in the second measurement region, a second pump light which is modulated according to a second modulation condition that is different from the first modulation condition and the probe light intersect inside the cell,
the optically pumped magnetometer further comprising a detection unit that detects the probe light.

4. The optically pumped magnetometer according to claim 1, wherein:
in the first measurement region a first pump light and a first probe light intersect inside the cell, and in the second measurement region a second pump light and a second probe light intersect inside the cell,
the optically pumped magnetometer further comprising a first and second detection unit that detect the first and second probe lights, respectively.

5. The optically pumped magnetometer according to claim 1, wherein the alkali metal atoms are at least one type of atom selected from a group including potassium, rubidium and cesium.

6. The optically pumped magnetometer according to claim 1, wherein the alkali metal atoms include potassium and rubidium.

7. The optically pumped magnetometer according to claim 1, wherein the relaxing light optical system includes a relaxing light shaping unit.

8. The optically pumped magnetometer according to claim 1, wherein the relaxing light has a wavelength that is a D1 transition resonance wavelength or a D2 transition resonance wavelength of the alkali metal atoms.

9. The optically pumped magnetometer according to claim 1, wherein a wavelength of the relaxing light is in a range of 770.1 nm±10 nm, a range of 766.7 nm±10 nm, a range of 795.0 nm±10 nm, a range of 780.2 nm±10 nm, a range of 894.6 nm±10 nm, or a range of 852.3 nm±10 nm.

10. An optically pumped magnetometer that, by causing a pump light having a circularly polarized light component and a probe light having a linearly polarized light component to intersect at an intersection region inside a single cell encapsulating alkali metal atoms, and detecting the probe light after passing through the intersection region, acquires information relating to a magnetic field intensity of the intersection region, comprising:
a relaxing light optical system that radiates a relaxing light which relaxes spin polarization of alkali metal atoms that are present at the intersection region inside the cell and which takes one part of the intersection region as a measurement region.

11. A method for acquiring information relating to a magnetic field intensity of a region inside a single cell encapsulating alkali metal atoms, comprising:
a step of radiating a pump light having a circularly polarized light component and a probe light having a linearly polarized light component so as to cause the pump light and the probe light to intersect at a plurality of measurement regions;
a step of acquiring information relating to a magnetic field intensity of the plurality of measurement regions by detecting the probe light that passes through the plurality of measurement regions; and
a step of radiating a relaxing light into the cell to relax spin polarization of alkali metal atoms that are present between the plurality of measurement regions.
